(19) United States
(12) Patent Application Publication
(10) Pub. No.: US 2019/0316247 A1
(43) Pub. Date: Oct. 17, 2019

(54) Laser ablation arrangement and method

(71) Applicant: Pulsedeon Oy, Tampere (FI)

(72) Inventors: Ville KEKKONEN, Jyväskylä (FI); Mikael SILTANEN, Hämeenlinna (FI)

(73) Assignee: Pulsedeon Oy, Tampere (FI)

(21) Appl. No.: 16/347,623

(22) PCT Filed: Oct. 20, 2017
(86) PCT No.: PCT/FI2017/050729

§ 371 Date: May 6, 2019

(30) Foreign Application Priority Data
Nov. 10, 2016 (FI) 20165846

(51) Int. Cl. C23C 14/28; G02F 1/35; B23K 26/12

(52) U.S. Cl. CPC C23C 14/28; B23K 26/1224; G02F 1/3515

(57) ABSTRACT

The present invention introduces a laser ablation arrangement and a corresponding method for PLD applications, where circular scanning patterns are utilized to achieve high scanning velocities on target surfaces for efficient coating process. The arrangement allows for flexible positioning of targets and scan lines in order to optimize coating uniformity on large surface areas as well as high duty cycle for scanning. These features are all essential for achieving efficient industrial coating processes. Fast optical switching and synchronized rotation of scanning mirrors enable efficient distribution of laser energy along long scan line paths on target surfaces.

### FIELD OF THE INVENTION

The present invention relates to laser scanning in pulsed laser deposition (PLD) and coating various materials with this technology.

### BACKGROUND OF THE INVENTION

Pulsed laser deposition is a technology where short laser pulses are used to detach and release material from a solid target, a process known as laser ablation, and the detached material will travel onto a substrate or base material, where it adheres and forms a coating. The laser source can be designed so that the wave-length, pulse length, pulse energy, and repetition rate of the pulses can be controlled or selected. Furthermore, optics may be used in order to control, for example, the polarization, spot size, and intensity distribution of the laser pulses on the target surface. Under some conditions, the detachment of the material can occur without significant thermal heating on the target surface.

The laser pulses can be scanned on the target surface in order to increase the area being coated by the released material and to enable smooth wear of the target. In addition, the substrate can be moved in the coating area in order to coat a larger area on the substrate. Together these two, efficient laser scanning and substrate manipulation, make the pulsed laser deposition method more applicable to industrial coating processes.

The productivity of the PLD based methods is of high interest, and it is highly desired to be increased compared to prior art coating solutions. One way of improving the productivity or effectiveness of the PLD based coating methods is to increase both the repetition rate of the laser pulses and the scanning velocity of the laser on the target. High scanning velocities can be achieved by a rotating optical element, like a mirror, in which the laser pulses are directed to. When the mirror is rotated around an axis, the reflecting laser pulses will be distributed to an angle defined by the optical setup. Polygon mirrors together with specific scanning lenses are a common and commercially available way of achieving high scanning velocities of focused laser beams on planar surfaces. A simple realization of scanning based on rotating optical element is a rotating monogon mirror, with one reflecting surface, which can produce a circular scan line around the axis of rotation, quite much with the same principle as in a lighthouse. Still, there are various optional setups, how these optical arrangements can be utilized in pulsed laser deposition with several possibilities to place the target with respect to the optical element(s) and what physical shape does the target have.

F1 20146142 presents and describes a scanning principle for a PLD based coating method, where a mirror is rotated around an axis and the reflected laser pulses are directed on the surface of a ring-shaped circular target, and thus, the ablation spot will move along a circular path on the target surface. The ablated material is ejected from such a circular line forming a ring-shaped source of material. Furthermore, the scanning arrangement using the rotating mirror can be equipped with a protective structure fixed with the mirror, where the structure incorporates only a small gap for the outgoing laser pulse sequence so that the detached target material will not substantially propagate back onto the surface of the reflecting mirror as potentially harmful contamination. One drawback in this approach is that the thickness uniformity of the coating resulting from ablation of a full circular path is not optimal for certain applications. Furthermore, most potential ways of improving the level of thickness uniformity would need complicated manipulation of the substrate to be coated and lead to a reduced duty cycle and effectiveness of the coating process and/or to an increase in the amount of waste material.

### SUMMARY OF THE INVENTION

The present invention introduces an efficient scanning method and arrangement incorporating at least two targets, fast optical switching and rotational scanning for directing laser pulse sequences onto these targets.

### BRIEF DESCRIPTION OF THE DRAWINGS

FIG. 1 illustrates a first scanning arrangement with two semi-circular targets, a fast optical switch and two rotating scanning mirrors, at an end of a first scanning phase;

FIG. 2 illustrates the first scanning arrangement at a start of a second scanning phase;

FIG. 3 illustrates a second scanning arrangement with four targets, 90 degrees arcs and two mirrors;

FIG. 4 illustrates the second scanning arrangement with six targets, 60 degrees arcs and three mirrors;

FIG. 5 illustrates the second scanning arrangement with three targets, 120 degrees arcs and three mirrors;

FIG. 6 illustrates a side view of an arrangement with a rotating mirror, a movable tilted-surface target and a substrate;

FIG. 7 illustrates a side view of an arrangement which changes the polarization of light in a quarter-wave plate;

FIG. 8 illustrates a side view of an arrangement which comprises also a focusing lens,

FIG. 9 illustrates a side view of an arrangement where the rotating mirror is placed at a different level with respect to the target;

FIG. 10 illustrates a side view of an arrangement where the target can be moved both horizontally and vertically;

FIG. 11 illustrates a side view of an arrangement where an additional reflecting surface is used for the propagating laser pulse sequence, with the target movable in two directions; and

FIG. 12 illustrates a side view of an arrangement where an additional reflecting surface is used for the propagating laser pulse sequence, with a tilted-surface target movable vertically.

### DETAILED DESCRIPTION OF THE INVENTION

The present invention introduces a laser beam scanning method and an arrangement applicable in the pulsed laser deposition (PLD) technology and its use in various coating applications. In other words, the invention discusses a laser ablation arrangement and a corresponding method.

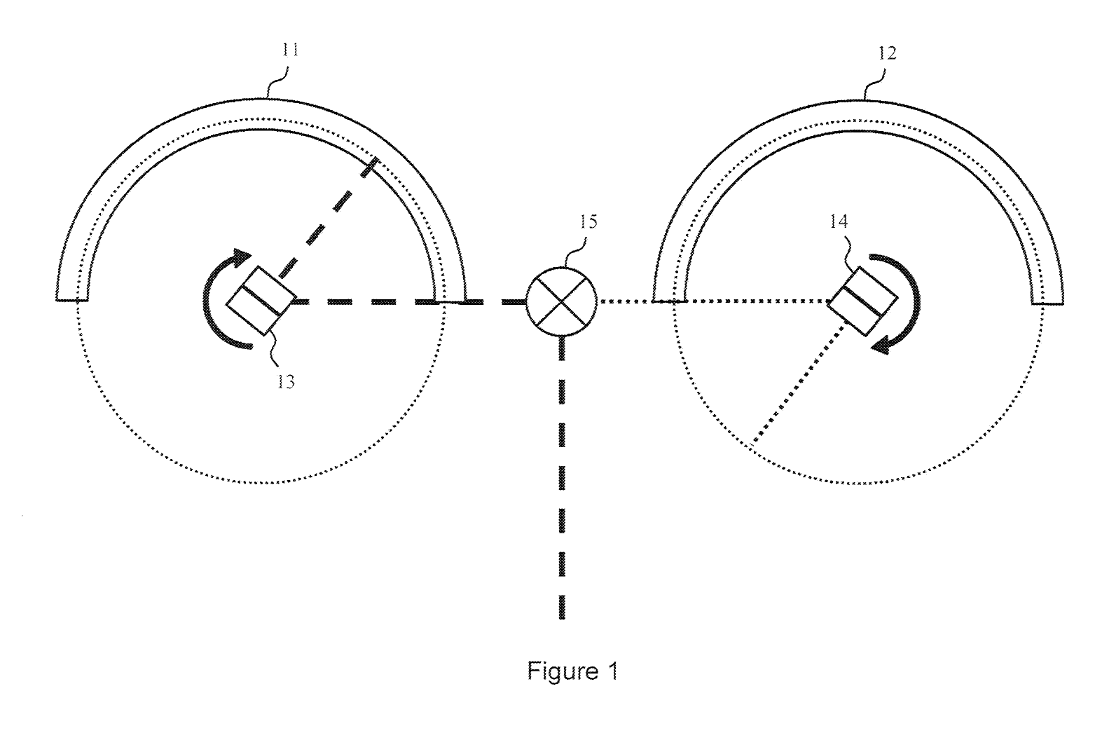

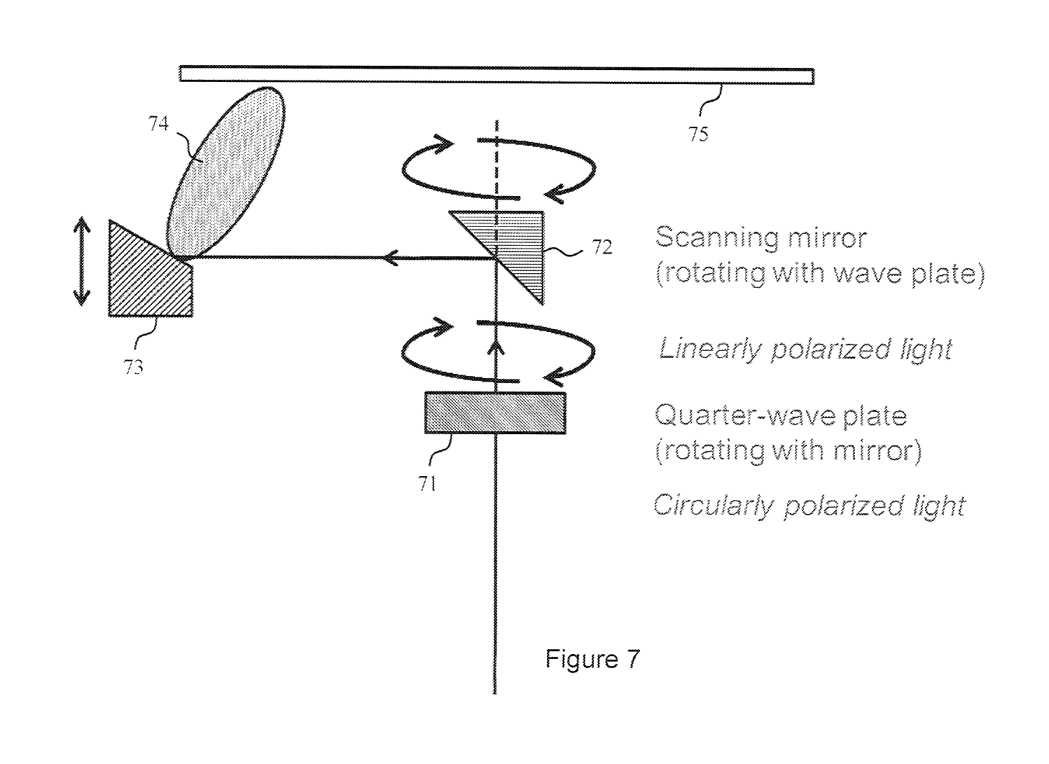

The present invention discloses a method for scanning short laser pulses on at least two different targets in an alternating fashion. FIG. 1 illustrates an example of the idea of a first scanning arrangement, showing a simplified top-down view. There are two targets 11, 12 identical in shape, shown as arcs, each being one half of a complete circular ring. In this case, both of the targets 11, 12 have their own rotating scanning mirrors 13, 14 at a distance defined by radius of curvature of the targets such that the centre point of a target 11, 12 lies on the axis of rotation of a mirror 13, 14. This means that if a focused laser beam is scanned by the rotating mirror 13, 14, the beam focus would be accurately on the curved surface a target 11, 12 during the scan. In this example, the axes of rotation of the mirrors 13, 14 are perpendicular to plane of the paper. The laser beam propagates to the mirror along the axis of rotation of the mirror. This is illustrated in connection with FIGS. 7-12 as well. The axes of rotation of the mirrors don't need to be parallel.

The target material can be selected freely in view of the used application. It is also possible to have targets which are all of different materials and thus generate coatings with different compositions or multi-layered coatings. The target may have a single material or it can be a multi-material object, such as a laminated object. Desired coating materials may vary significantly in their characteristics.

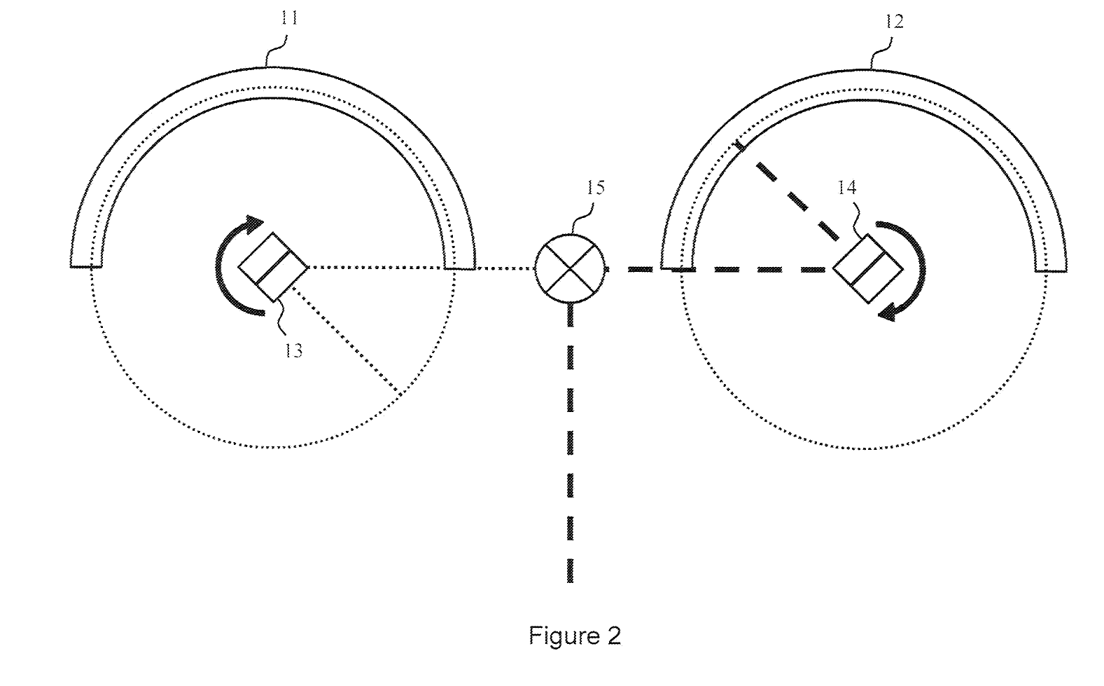

The scanning mirrors in the example of FIG. 1 are set to rotate synchronized at the same angular speed, not necessarily to the same direction, by a controller. An optical switch 15, comprising for example an electro-optic modulator (EOM) and a polarizing beam splitter, selectively switches the laser beam to travel to either mirror 13 or mirror 14. The angular displacement of the mirrors 13, 14 and the timing of the switching are set such that in the first phase of the scanning, mirror 13 scans the laser beam on the first target 11. Once mirror 13 reaches end of scan on target 11 (half a turn), the laser beam is switched to mirror 14 which will be on the start of scan on the second target 12. This second phase of the scanning is illustrated in FIG. 2, with the same physical parts as already discussed in FIG. 1. During the second phase of the scanning, when mirror 14 scans the laser beam on target 12, also mirror 13 rotates half a turn reaching an angular displacement for start of scan on target 11. The beam is switched again back to mirror 13 and phase 1 is repeated. The scanning continues in this alternating fashion and is in effect a full circular scan with one rotating mirror and one full circle ring target. This means that the duty cycle of the scan is close to 100%, affected only minimally by the short time required for the switching. However, having the target ring split into two halves allows for different geometrical arrangements for positioning the targets with respect to the substrate being coated, and thus allows for example optimizing the uniformity of the coating.

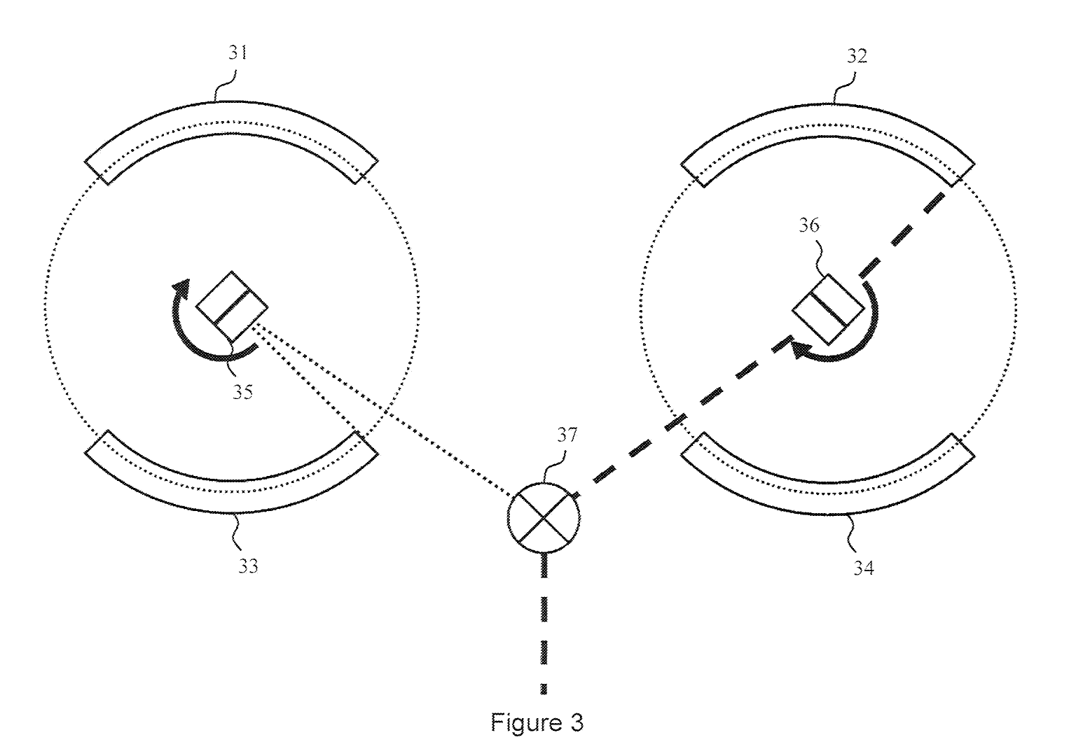

Based on the basic principle shown in FIGS. 1 and 2 and described above, rotating scanners and circular arc targets can be arranged in many different ways. FIGS. 3-5 show some examples where identical circular arc targets, together forming a complete circle, have been positioned in various configurations.

FIG. 3 illustrates a scanning arrangement comprising four targets 31, 32, 33, 34 which each covers an angle of 90 degrees from a complete circle. As it can be seen from FIG. 3, two groups comprising two oppositely locating target segments for both groups are based side-by-side. The first group on the left comprises targets (segments) 31 and 33, while the second group on the right comprises targets 32, 34. In the centre of the circle surrounded by the targets of the first group 31, 33 locates a first mirror 35 rotating clockwise in this example, and correspondingly, in the centre of the second group of targets 32, 34 locates a second mirror 36 rotating also in a clockwise direction. At first the optical switch 37 directs the laser pulses onto the first group of targets, and more specifically, to the target 31. When the reflected beam from the first mirror 35 has covered the whole 90 degrees of the target 31, the optical switch will turn the laser pulses onto the target 32 and its left-hand side edge in the situation of FIG. 3. The mirrors will both turn once again 90 degrees, and the switching will happen once again, this time into target 33. The full 360 degrees of ablation from all the segmented targets is completed after the switching is made once again onto target 34, and when that segment is finished (in its left-hand side end in this figure). Thereafter the disclosed circle can start again from target 31, and the method continues in similar fashion as disclosed above.

Of course, the locations of the optical switch 37 and the ablated targets 31-34 need to be selected so that there is a line of sight always for the laser pulses in a way that the laser pulses from the optical switch 37 reach the mirror 35 or 36 and the reflection from the mirror 35 or 36 will uninterruptedly reach the desired target segment. The intelligent controlling of the rotational movements and angular positions of the mirrors 35, 36, together with the controlling of the optical switch 37 can be implemented by a controller unit which is programmable.

The dashed lines in FIG. 3 illustrate the moment when ablation on the second target 32 has just finished, and the third target 33 is about to start (as the dotted lines show), triggered by the action made by optical switch 37.

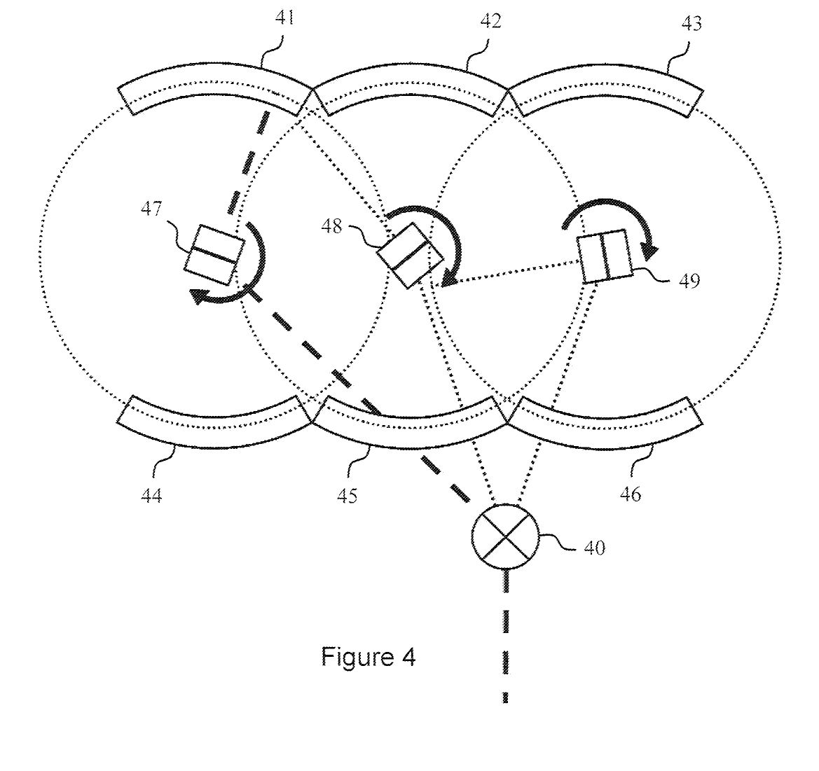

FIG. 4 illustrates a further embodiment of a possible segmented target arrangement. This example comprises six targets 41-46 where each target has a 60 degrees arc. These targets are placed in a form of three circular groups, with two targets placed oppositely to one another in each group. The mirror for the first group is mirror 47, the mirror for the second group is mirror 48, and the mirror for the third group is mirror 49. All mirrors rotate here in a clockwise direction. The optical switch 40 controls the laser pulses to each of these mirrors 47-49 in an accurately controlled, time-sensitive manner.

The time instant in FIG. 4 illustrates the moment where about the first 80% along the first segmented target 41 has been scanned. Respectively, the reflection angles in mirrors 48 and 49 are shown through the imagined directions of the reflected laser pulses, in case the optical switch would have acted towards the other mirrors 48, 49.

In this example as well, the cumulative angle of all the six segmented targets equals 360 degrees.

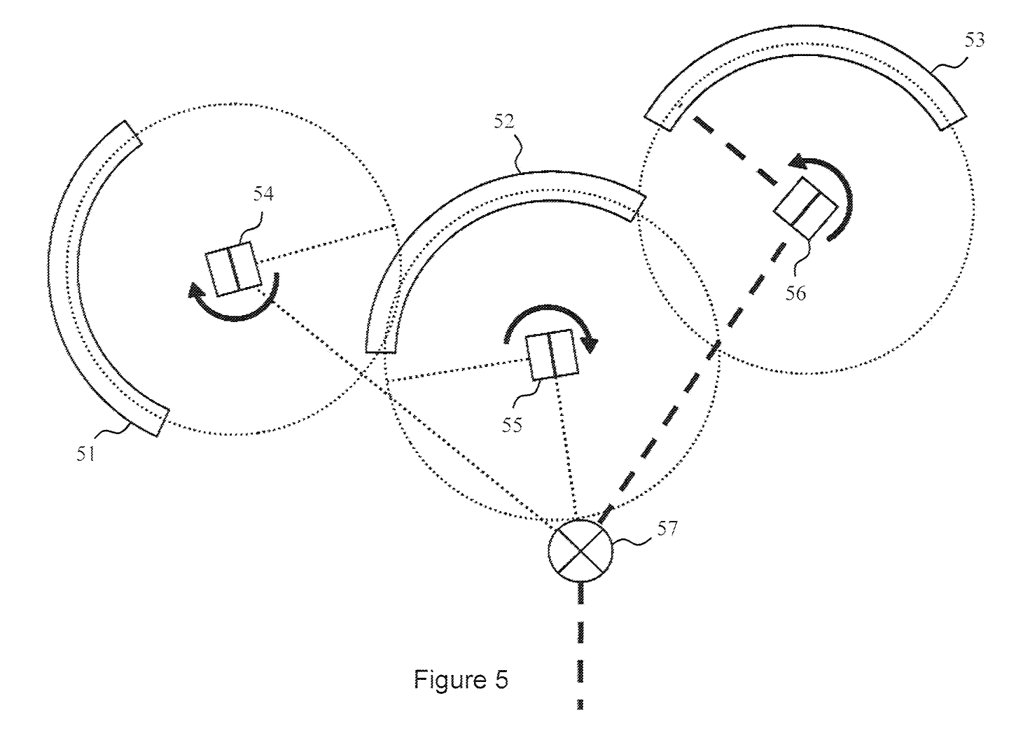

FIG. 5 illustrates yet another embodiment of segmented targets and their mutual locations. In this example, there are three segmented targets 51, 52, 53. Each of the targets have an arc of 120 degrees. These targets as combined would result into a 360 degrees angle, i.e. a complete circle. In this example, it is notable that the rotational directions of the targets can be opposite between any two rotating targets. In this example, the third target 53 rotates in a counter-clockwise direction, while the first 51 and the second targets 52 rotate in a clockwise direction. As in the earlier corresponding examples, the first mirror is mirror 54 in the center of the arc of the first target 51. The second and the third mirrors are mirrors 55 and 56, respectively. The optical switch 57 acts as the controlling element between the laser source (not shown in the figure) and the correct target.

The time instant shown in FIG. 5 depicts the situation where the third target 53 has been scanned about 90% of its total arc length. After the third target 53, the scanning will move onto the second target 52. Thereafter, the first target 51 will be scanned starting from the bottom edge of the target 51.

Many other possible variations are still available in the present invention. The main condition for the circular arc targets is that the summed angle of the arcs of the all targets in the arrangement is 360 degrees (meaning a full, single round) in order to reach maximum duty cycle for the laser and optimal utilization of the target materials. Arrangements with multiple laser sources and different arc sizes are also possible.

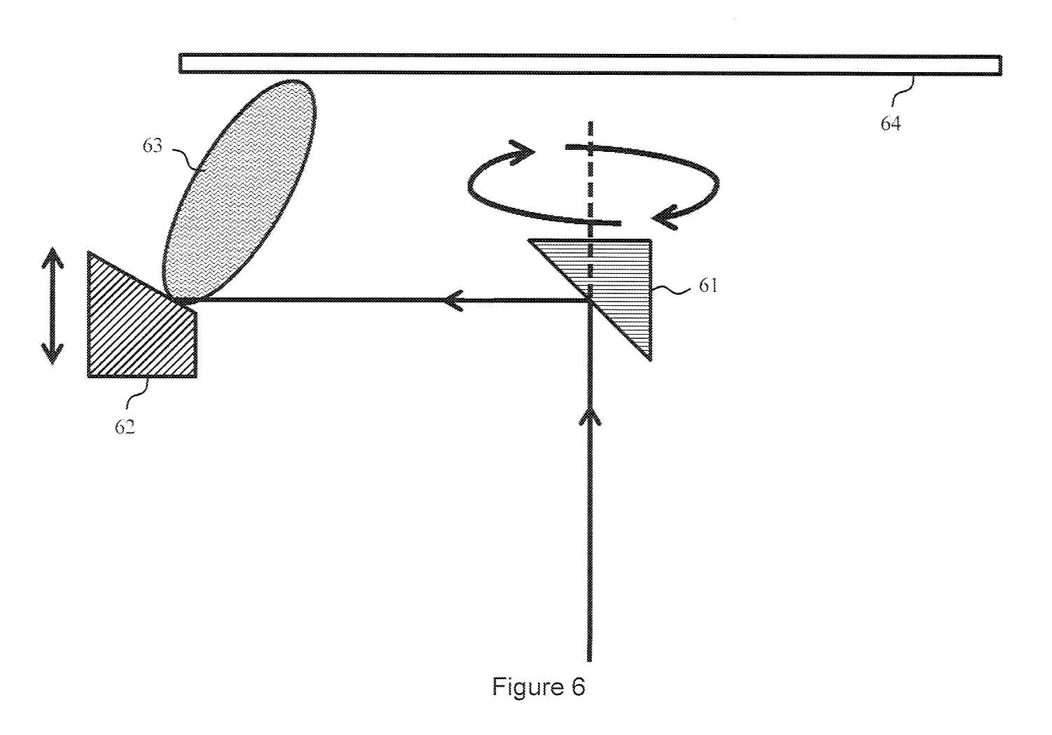

FIG. 6 shows a side view of an arrangement with a rotating mirror 61, a movable tilted-surface target 62 and a substrate 64, according to one embodiment of the invention. The mirror 61 may be a triangularly shaped reflecting element. When looking at the cross-sectional image, the target 62 may have a shape of a trapezium. When the reflected laser pulse sequence hits the outermost edge of target 62, the tilted angle in the targets results in a beneficial direction for the detached material 63. This means that the detached material will not in great extent propagate back towards the mirror 61, but the detached material 63 flow can be directed towards the substrate 64. In this example, the substrate 64 is planar. Also, a roll-to-roll-type of method can be applied in order to release the substrate from a first roll to a coating region and to gather the coated substrate from the coating region onto a second roll. Furthermore, as shown in FIG. 6, the tilted-surfaced target 62 may be lifted up or lowered down in order to reveal new scanning lines on top of the target surface. This ensures a smooth wear of the target surface during prolonged ablation sessions.

FIG. 7 illustrates a side view of an arrangement for controlling the polarization of the laser pulses. The laser light emitted from the laser source, and also after the optical switch, can be linearly polarized light. First, a quarter-wave plate (non-rotating, not depicted) is used to transform the polarization of the laser pulses from linear polarization into circular polarization. Thereafter, a quarter-wave plate 71 rotating with the mirror generates from the circularly polarized light linearly polarized light which rotates with the scanning mirror 72. The linearly polarized light will reflect from the scanning mirror 72, which also rotates. The linearly polarized laser pulse sequence will then make contact with the outer surface of a target 73. Ideally, this arrangement provides the same polarization characteristics of the laser light upon incidence both on the rotating mirror surface and on the target surface and, thus, the same ablation conditions throughout the scan on the circular target. In this example, the target 73 has similar characteristics as the target 62 of FIG. 6 does. As a result of the ablation, material 74 will be detached and ejected from the surface of the target 73. The ejected material 74 propagates forward towards the substrate 75 and adheres and condences onto it, thereby forming a coating layer, or a part of a complete coating.

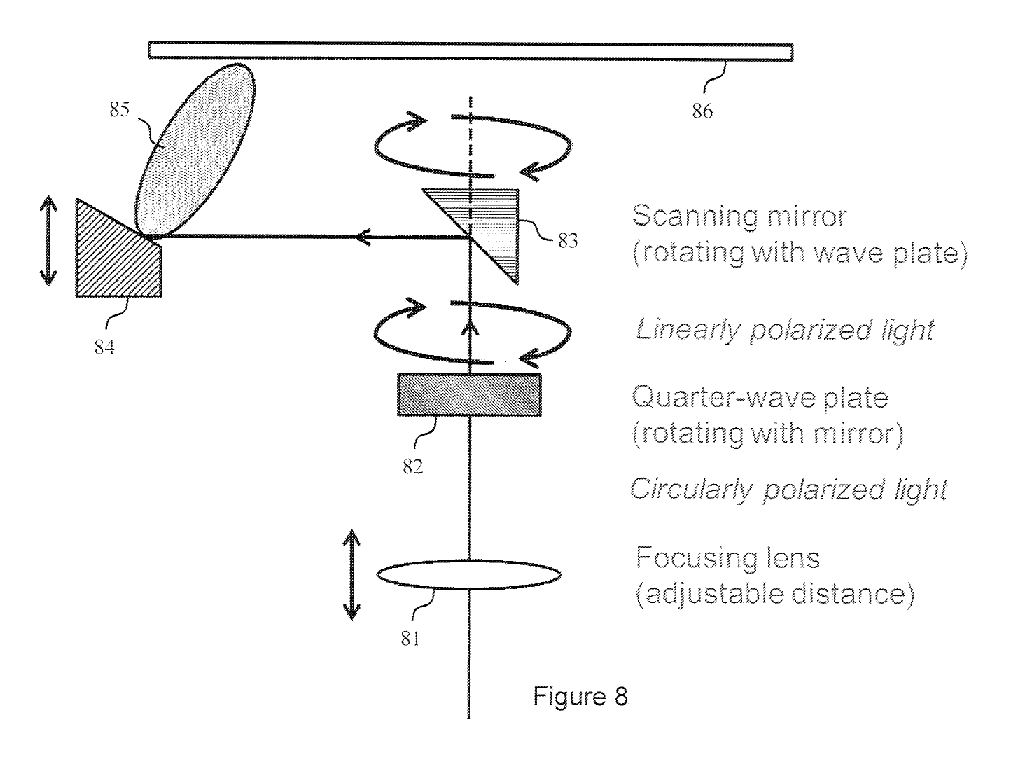

FIG. 8 illustrates yet another embodiment of the scanning arrangement, comprising also a focusing lens 81. The focusing lens 81 is placed between the optical switch and the quarter-wave plate 82. The beam path length from the focusing lens 81 to the target 84 surface can be changed by adjusting the position of the focusing lens 81, in order to ensure a proper focusing onto the target 84 surface. Also the spot size may be adjusted with the focusing lens 81. The movement of the focusing lens 81 is needed in order to generate constant laser spot size on the target 84 surface when the target is moved for ablation of the whole target surface.

Other elements are in line with FIG. 7. In other words, the scanning mirror 83 will rotate with the same angular speed and direction as the quarter-wave plate 82 does. The detached material 85 emerging from the target 84 surface will be directed towards the substrate 86, where it adheres to and forms a coating or part of it.

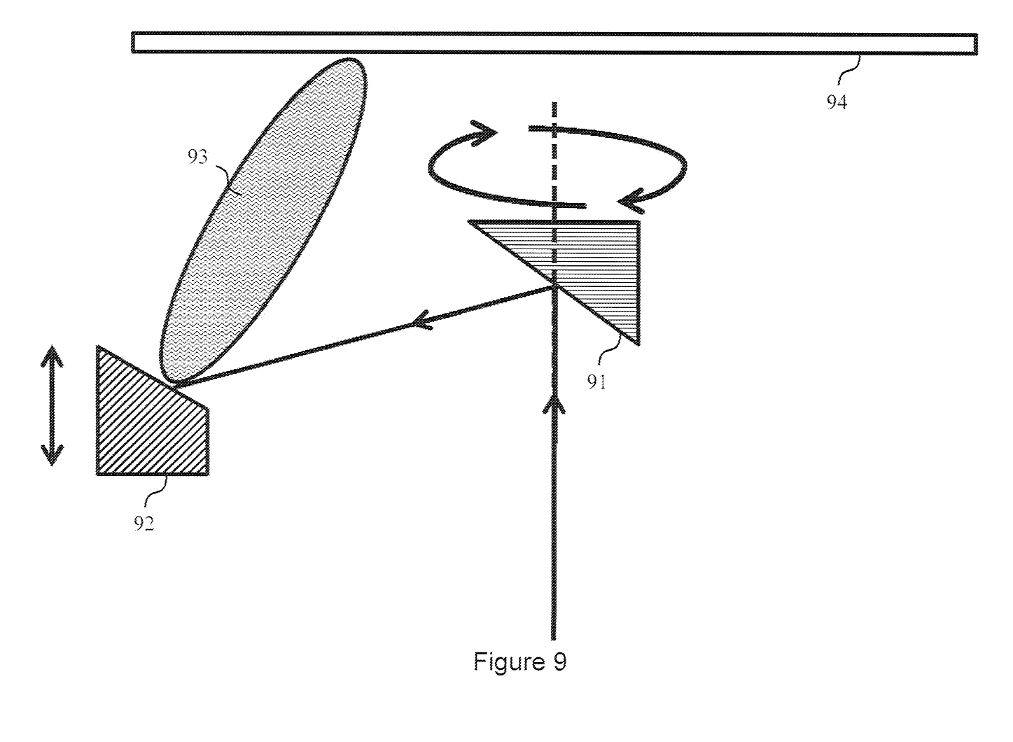

FIG. 9 illustrates a side view of an arrangement where the rotating mirror 91 is placed above the plane of the target 92. The main difference in the embodiment according to FIG. 9 compared to earlier embodiments is that the angle of incidence of laser pulse sequence on the mirror 91 is other than 45 degrees. This exemplifies the possibility to arrange the components and their orientation in the setup such that the direction of the ejected material 93 detached from the target 92 is optimal with respect to the substrate 94. By also tuning the height of the target 92, the scanning line can be controlled intelligently to ensure smooth and uniform wear of the target 92.

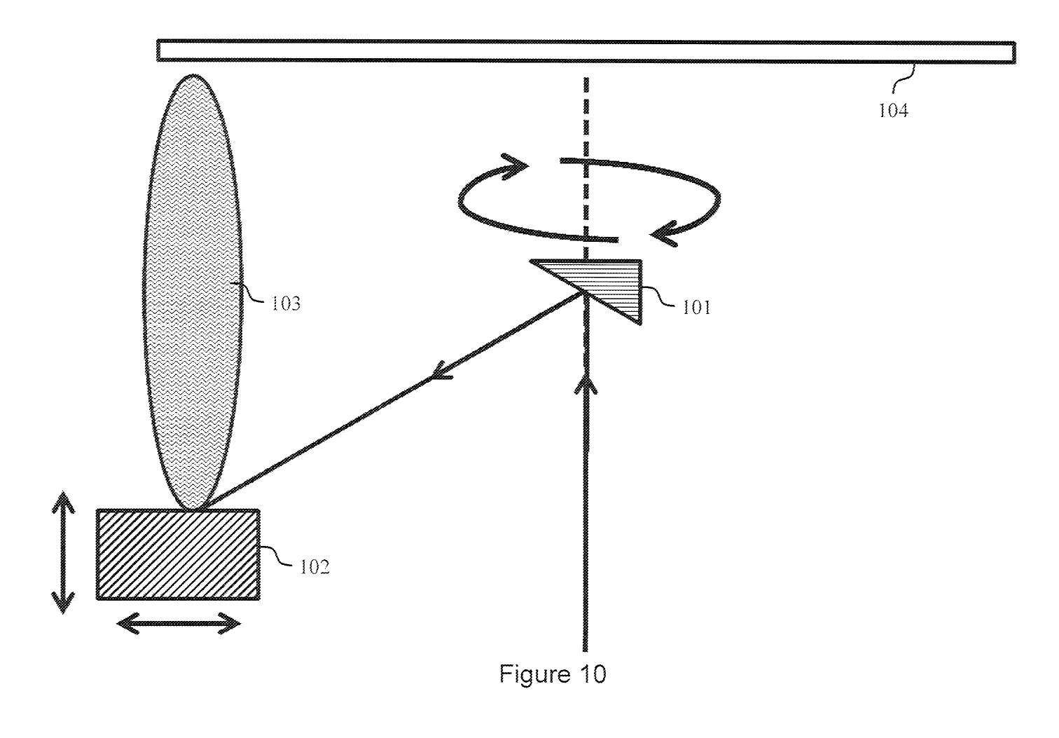

FIG. 10 illustrates a side view of an arrangement where the target 102 can be moved both horizontally and vertically. Furthermore, the cross-sectional side view of the target 102 is a rectangle. This embodiment has otherwise the same principle as the embodiment of FIG. 9 but with the two-directional movement possibilities for the target 102, both the scanning line location on the target 102, and also the distance between the target 102 and the substrate 104 can be easily controlled. This allows for various scanning patterns on the target 102 surface for smooth and uniform wear of the target 102. The detached material 103 flow may even have the same direction as the incoming laser pulse sequence towards the mirror 101. In this example, the reflecting angle in the mirror 101 is less than 90 degrees.

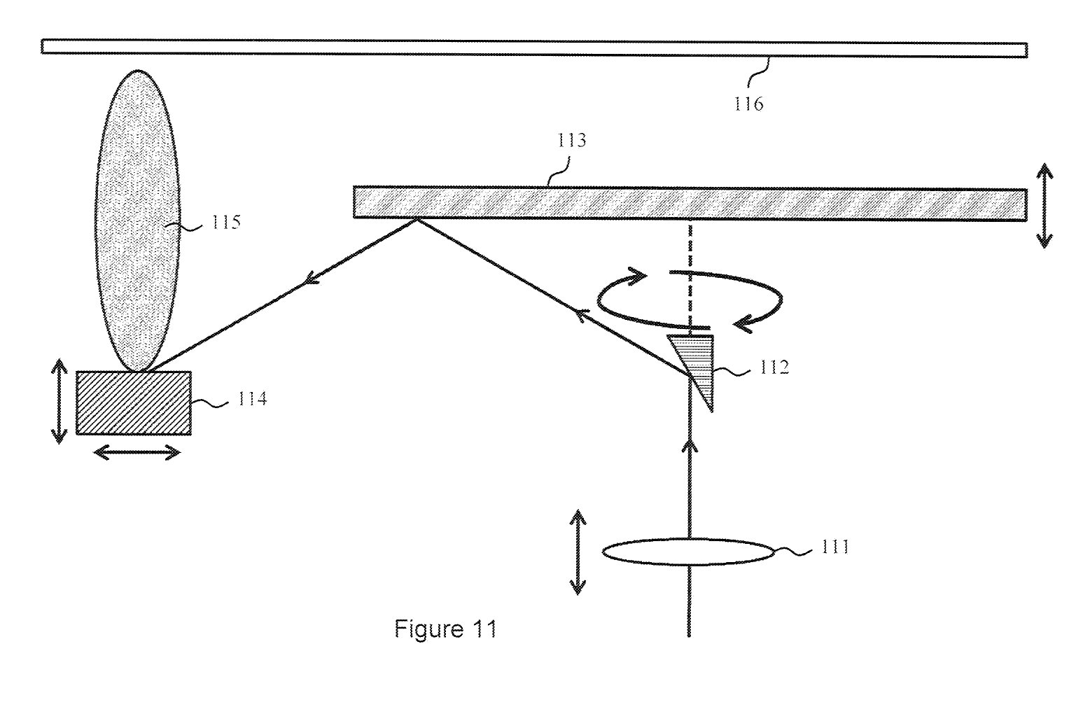

FIG. 11 illustrates a side view of an arrangement where an additional reflecting surface 113 is used for the propagating laser pulse sequence, with the target 114 movable in two directions. The arrangement comprises a focusing lens 111 and a mirror 112 directing the incoming laser light towards a blunt angle (between 90 and 180 degrees). Thereafter, the reflected laser pulse sequence makes contact with an additional reflecting surface 113 whose height with respect to the mirror 112 can be adjusted in this example. Furthermore, in this example the additional reflecting surface 113 is placed in a horizontal direction in this side-view image. This arrangement enables scanning of the laser pulse sequence on the target 114 surface by the rotation of the mirror 112 together with movement of the additional reflecting surface 113. Movement of the target 114 might not be necessary at all in this configuration, but could be used for compensating the wear of the target 114 or for generating additional scanning patterns.

After the additional reflection, the laser pulse sequence is directed on the surface of the target 114 according to the invention, where the target 114 has similar characteristics as the target 102 in FIG. 10 has. The detached material 115 will propagate in an upwards direction (or some other selected direction), and finally, it will face and adhere onto the surface of the substrate 116.

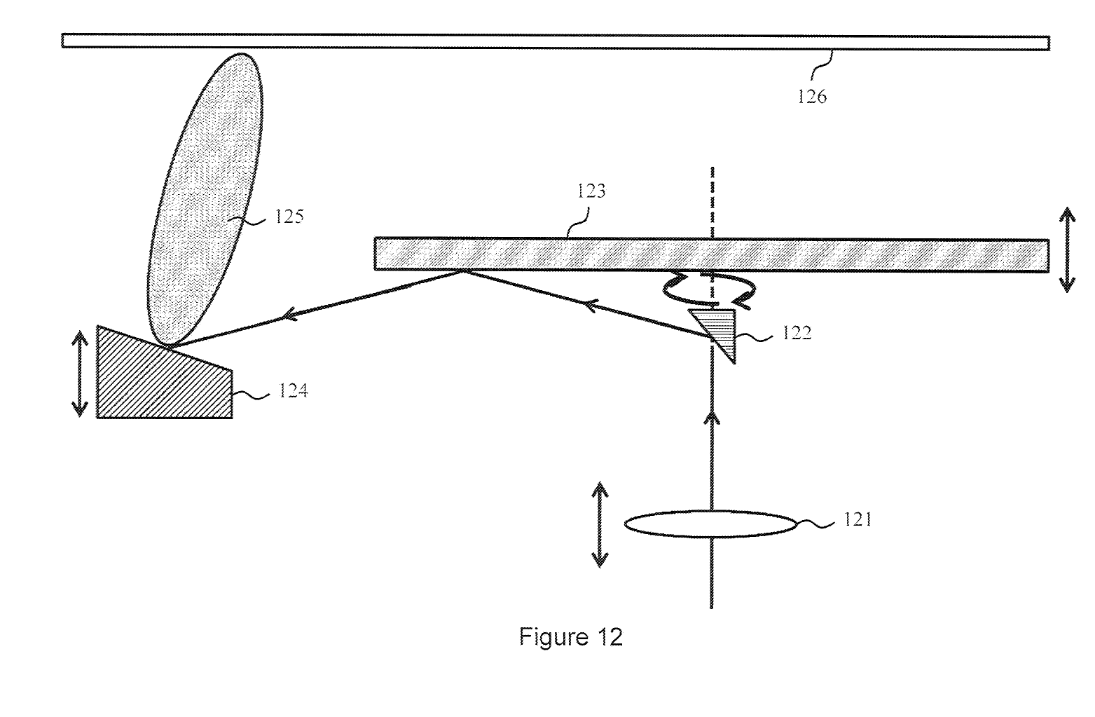

Finally, in yet another embodiment of the invention, FIG. 12 illustrates a side view of an arrangement where an additional reflecting surface 123 is used for the propagating laser pulse sequence, with a tilted-surface target 124 movable in a vertical direction. The arrangement also comprises a focusing lens 121, and the rotating mirror 122 which performs a blunt-angled reflection on the incoming laser pulse sequence. The additional reflecting surface 123 may be adjusted in its height, and the reflected laser pulse sequence affected by the additional reflecting surface 123 will finally hit the surface of the tilt-surfaced target 124. The target 124 height can be adjusted. The result after this collision of laser pulses onto the target 124 is the detaching material 125 cloud. The detached material 125 will reach, contact and adhere onto the surface of the substrate 126, and thus, it forms a coating or part of a coating onto the substrate 126.

It is to be noted that these examples do not necessarily represent any optimal configuration, but display the possibilities and degrees of freedom related to the present invention. Furthermore, it is possible to use several laser sources and targets of different sizes in the same setup.

Next various other elements of the arrangement are discussed, and also different parameter options available for different elements of the arrangement. Also some clarifying features and characteristics are discussed in more detail for the parts already introduced in the above paragraphs.

The energy for the coating arrangement arrives from a laser source whose parameters can be controlled by a control unit. The laser source is able to emit very short laser pulses where the pulse length can be selected, e.g., from a range of 500 fs . . . 100 ns. Furthermore, the repetition frequency of the laser pulses can be selected e.g. from a range of 100 kHz . . . 100 MHz by the control unit. Also the energy of a single laser pulse can be specified, and in one embodiment, it is selected to be in a range of 2 μJ . . . 100 μJ.

Still, in the present invention, the disclosed scanning principles do not limit applicable laser parameters. However, the foreseeable benefit comes from use of high pulse repetition rates which require high scanning velocities on the target surface in order to achieve separation of pulses. Efficient distribution of the laser power onto larger surface area (longer scanning path) allows for utilization of high average laser power. These are important factors when considering the industrial applicability of the pulsed laser deposition method.

For example, separation of pulses arriving at a repetition rate of 40 MHz, the pulses having a spot size of 50 μm on the surface of the target would require scanning velocity of 2000 m/s. In the case of a circular arc target with a radius of curvature of 500 mm, this requires rotation of the scanning mirror at 40000 rpm.

The laser pulse string, i.e. a sequence of laser pulses, is directed to one or more optical elements, which can be used to focus the laser spot accurately to a desired distance, and also for selecting and tuning the spot size for the laser pulses. In the case of Gaussian intensity distribution, the spot diameter of a single laser pulse can be defined as “FWHM” (Full Width at Half Maximum) or as a width at intensity level equal to 1/e² times the intensity peak value. For simplicity reasons, only a single optical element is depicted but in an actual arrangement, there can be a plurality of various elements which reflect, focus and/or otherwise manipulate the incoming laser pulses and their intensity distributions. The optical element may be a lens, a mirror, a diffracting element, a wave plate, a polarizer, or a filtering element.

The arrangement comprises optical switching means, which are configured to direct the incoming laser pulses to a desired scanning mirror at desired time instants. These time instants are defined by the geometrical arrangement of the mirrors and targets and rotation speeds of the mirrors. In one embodiment, the mirror (which can be a planar object, or outside surfaces of a triangular or a polygon element) can be rotated around an axis in order to achieve the desired alignment angle.

If the target is a ring-shaped or a toroid-shaped or a circular plate, the angle formed between the incoming laser pulse sequence and the reflected laser pulse sequence in the reflecting element can be a blunt angle but it can alternatively be an acute angle, or a right angle.

When the scanning mirror rotates, preferably in a constant angular velocity, the ablation spot moves along the surface of the first target. After the rotation of 360 degrees from the start, the ablation spot will coincide with the earlier effected scanning line. In general, uniform wear of the target surface is preferred for stability of the ablation and deposition conditions, especially in industry where processes are run over longer periods of time. In order to avoid overlapping of sequential scan lines and formation of deep grooves on the target surface as a result of the overlapping, either movement of the target with respect to the scan line or movement of the scan line on the target is required. The movement can be set as a step-like change at given time instants or as a slow, continuous movement. The direction of this movement depends on the target geometry and scanning arrangement. In some cases, the movement will lead to a change in distance between the target surface and optics. In these cases, there needs to be movement of the optics synchronized with the movement of the target in order to maintain the laser beam properties and ablation conditions on the target surface. The scan line can be moved by movement of the scanning mirror and optics or by an additional moving mirror between the scanning mirror and the target.

A laser pulse hitting the target will be partly absorbed into the material and partly reflected, the absorption depth and the amount of absorbed and reflected energies depending on the properties of the target and the laser pulse. In suitable conditions, a single laser pulse can lead to ablation, i.e. removal and release of material from the surface of the target. The material ejected by the laser ablation may contain ionized material (plasma), excited or neutral atoms (vapor), charged or neutral particles, fragments of target material depending on the properties of the target material and the laser pulse. Material removal may also be a result of a cumulative process where several subsequent laser pulses hit the same area on the target.

The fraction of the energy absorbed in the target material but not consumed in the material removal process will contribute to increasing the temperature of the target. Generally, shorter laser pulses will cause less thermal effects in the target material. However, in addition to pulse length, also other factors, such as laser wavelength as well as spatial and temporal intensity distributions of the laser pulse, affect the behavior.

In suitable conditions, the material ejected from the target can travel to a surface of a substrate. The substrate (not shown in FIG. 1) can be placed to an appropriate location in the vicinity of the first target so that the flow of ejected material hits the surface of the substrate, condenses and adheres onto it forming a thin layer of material. The substrates are in many cases planar sheets which can be placed either stationary, or in order to increase productivity of the coating process, as a moving substrate sheet by e.g. applying a roll-to-roll principle. The substrate can have almost any shape and size, but coating uniformity and properties are limited by the line-of-sight nature of the PLD process as well as by possible means to manipulate objects to be coated.

The whole PLD arrangement is conventionally placed in an enclosed chamber where vacuum conditions can be achieved. Also gaseous materials can be fed into the chamber in a controlled way and the pressure of the chamber can thus be accurately controlled. Also some protecting means (not shown) can be used in the chamber in order to protect the optical elements such as mirrors and lenses from the contamination created by the detached material possibly propagating backwards onto the optical elements. This may be a physical cover object which may have small gaps for the travelling laser pulses to go through.

Laser source parameters can of course be set and changed either initially or during the PLD process, when desired.

As a summary of the present invention and its embodiments, the present invention introduces a laser ablation arrangement for coating a substrate. The arrangement comprises a control unit; at least one laser source emitting laser pulses; at least two targets, where the ablation surface of each of the at least two targets is formed as a circular arc; at least two controllable scanning mirrors which are each rotatable around its axes, respectively, and which scanning mirrors are configured to rotate synchronized at the same angular velocity with one another; a controllable optical switch which can direct incoming laser pulses to at least two different paths, where the incoming laser pulses are pointed on the optical switch and the output pulses are directed to a selected scanning mirror at a time, and further at a selected target among the at least two targets, wherein the control unit is configured to activate the optical switch in selected time periods so that ablated material is detached from the at least two targets consecutively, in order to form a coating on the substrate.

In one embodiment of the invention, the arcs of the targets as summed together form a complete circle.

In one embodiment of the invention, a substrate is placed in a close distance of the targets, in order for the ablated material to adhere onto the substrate as a single-layered coating or as a multi-layered coating.

In one embodiment of the invention, there are two targets which are manufactured of different materials or material compositions.

In one embodiment of the invention, the target is shaped like a torus, a cylinder, a cone, a truncated cone, or a cylinder-shaped element inclined or beveled at its end, or the target is a plate.

In one embodiment of the invention, during the ablation process, the control unit is configured to control the rotation of all scanning mirrors simultaneously, and an optical switch is arranged to direct the laser pulses to the selected scanning mirror for a given time period.

In one embodiment of the invention, the laser pulses arriving to the target surface are linearly or elliptically or circularly polarized.

In one embodiment of the invention, the rotation speed is selected to be mutually the same for all scanning mirrors by rotating means.

In one embodiment of the invention, the rotation axes of the at least two of the scanning mirrors are aligned in parallel with one another.

In one embodiment of the invention, the first target is manufactured from a first substance, and the second target is manufactured from a second substance different from the first substance, wherein the arrangement is configured to manufacture a layered coating with alternating first and second substances on top of the substrate when the arrangement is switched on.

In one embodiment of the invention, the arrangement comprises two semi-circular targets.

In one embodiment of the invention, the arrangement comprises three targets each having a 120 degrees arc.

In one embodiment of the invention, the arrangement comprises four targets each having a 90 degrees arc.

In one embodiment of the invention, the arrangement comprises six targets each having a 60 degrees arc.

In one embodiment of the invention, optical processing means are used between the laser source and the optical switch, and/or between the optical switch and the scanning mirror in use.

In one embodiment of the invention, the optical processing means comprise a quarter-wave plate which transforms the polarization of the incoming laser pulses from circularly polarized light into linearly polarized light.

In one embodiment of the invention, the optical processing means comprise at least one focusing lens whose longitudinal placement along the path of the propagating laser pulses can be adjusted.

In one embodiment of the invention, the placement of the target can be adjusted such that the distance between the scanning mirror and the target and/or the distance between the target and the substrate can be varied.

In one embodiment of the invention, an additional reflecting surface is placed between the scanning mirror and the target to be ablated, for directing the propagating laser pulses to a controlled ablation spot on the target.

Furthermore, the inventive idea of the present invention discloses also a corresponding laser ablation method for coating a substrate, which method comprises the steps of
emitting laser pulses by at least one laser source;
controlling rotation of at least two controllable scanning mirrors, each around its axis, respectively, by a control unit;
controlling an optical switch for guiding the laser pulses from the optical switch to a single selected scanning mirror at a time;
where the scanning mirrors rotate synchronized at the same angular velocity with one another, where the emitted laser pulses are pointed on the selected scanning mirror and the reflected pulses are pointed at a selected target among at least two targets, where the ablation surface of each of the at least two targets is formed as a circular arc; wherein
switching the emitted laser pulses from one scanning mirror to another scanning mirror in selected time periods so that ablated material is detached from the at least two targets consecutively, in order to form a coating on the substrate.

In one embodiment of the method according to the invention, the arcs of the targets as summed together form a complete circle.

The present invention is not restricted merely to the presented examples but the scope of the invention is defined by the following claims.

1. A laser ablation arrangement for coating a substrate, wherein the arrangement comprises
a control unit,
at least one laser source emitting laser pulses,
at least two targets having an ablation surface in a form of a circular arc,
at least two controllable scanning mirrors each rotatable around its axis, and which scanning mirrors are configured to rotate synchronized at same angular velocity with one another,
a controllable optical switch capable of directing incoming laser pulses to at least two different paths, where incoming laser pulses are pointed on the optical switch and output pulses are directed to a selected scanning mirror at a time, and further at a selected target from among the at least two targets, wherein
the control unit is configured to activate the optical switch in selected time periods so that ablated material is detached from the at least two targets consecutively, in order to form a coating on the substrate.

2. The laser ablation arrangement according to claim 1, wherein the circular arcs of the targets as summed together form a complete circle.

3. The laser ablation arrangement according to claim 1 wherein the substrate is placed in a close distance of the targets, in order for the ablated material to adhere onto the substrate as a single-layered coating or as a multi-layered coating.

4. The laser ablation arrangement according to claim 1, wherein there are two targets which are manufactured of different materials or material compositions.

5. The laser ablation arrangement according to claim 1, wherein the targets have a shape like a torus, a cylinder, a cone, a truncated cone, a cylinder-shaped element inclined or beveled at its end, or a plate.

6. The laser ablation arrangement according to claim 1, wherein during ablation process, the control unit is configured to control rotation of all scanning mirrors simultaneously, and the optical switch is arranged to direct the laser pulses to the selected scanning mirror for a given time period.

7. The laser ablation arrangement according to claim 1, wherein the laser pulses arriving to target surface are linearly or elliptically or circularly polarized.

8. The laser ablation arrangement according to claim 1, wherein rotation speed is selected to be mutually same for all scanning mirrors.

9. The laser ablation arrangement according to claim 1, wherein the rotation axes of the at least two scanning mirrors are aligned in parallel with one another.

10. The laser ablation arrangement according to claim 1, wherein a first target of the at least two targets is manufactured from a first substance, and a second target of the at least two targets is manufactured from a second substance different from the first substance, wherein the arrangement is configured to manufacture a layered coating with alternating first and second substances on top of the substrate when the arrangement is switched on.

11. The laser ablation arrangement according to claim 1, wherein the arrangement comprises two semi-circular targets.

12. The laser ablation arrangement according to claim 1, wherein the arrangement comprises three targets each having a 120 degrees arc.

13. The laser ablation arrangement according to claim 1, wherein the arrangement comprises four targets each having a 90 degrees arc.

14. The laser ablation arrangement according to claim 1, wherein the arrangement comprises six targets each having a 60 degrees arc.

15. The laser ablation arrangement according to claim 1, wherein optical processing means are used between the laser source and the optical switch, and/or between the optical switch and the scanning mirror in use.

16. The laser ablation arrangement according to claim 15, wherein the optical processing means comprise a quarter-wave plate which transforms the polarization of the incoming laser pulses from circularly polarized light into linearly polarized light.

17. The laser ablation arrangement according to claim 15, wherein the optical processing means comprise at least one focusing lens whose longitudinal placement along the path of the propagating laser pulses can be adjusted.

18. The laser ablation arrangement according to claim 1, wherein the placement of each of the at least two targets can be adjusted such that distance between the scanning mirror and the target and/or distance between the target and the substrate can be adjusted.

19. The laser ablation arrangement according to claim 1, wherein an additional reflecting surface is placed between the scanning mirror and the target to be ablated, for directing propagating laser pulses to a controlled ablation spot on the target.

20. A laser ablation method for coating a substrate, which method comprises the steps of
emitting laser pulses by at least one laser source,
controlling rotation of at least two controllable scanning mirrors, each around its axis, respectively, by a control unit;
controlling an optical switch for guiding the laser pulses from the optical switch to a single selected scanning mirror at a time;
wherein the scanning mirrors rotate synchronized at same angular velocity with one another, emitted laser pulses are pointed on a selected scanning mirror and reflected pulses are pointed at a selected target from among the at least two targets, and each of the at least two targets has an ablation surface in a form of a circular arc; and
switching emitted laser pulses from one scanning mirror to another scanning mirror in selected time periods so that ablated material is detached from the at least two targets consecutively, in order to form a coating on the substrate.

21. The laser ablation method according to claim 20, wherein the circular arcs of the targets as summed together form a complete circle.
